(19) United States
(12) Patent Application Publication
(10) Pub. No.: US 2016/0133826 A1
(43) Pub. Date: May 12, 2016

(54) METHOD OF MAKING LEAD-FREE CERAMIC COATING

(71) Applicant: AGENCY FOR SCIENCE, TECHNOLOGY & RESEARCH, Singapore (SG)

(72) Inventors: Kui YAO, Singapore (SG); Shuting CHEN, Singapore (SG); Ivan Chee Kiang TAN, Singapore (SG)

(21) Appl. No.: 14/932,457

(22) Filed: Nov. 4, 2015

(30) Foreign Application Priority Data
Nov. 6, 2014 (SG) 10201407285S

(51) Int. Cl. H01L 41/314; H01L 41/187

(52) U.S. Cl. CPC H01L 41/314; H01L 41/1873; H01L 41/1878; H01L 41/187

(57) ABSTRACT

A method of making a lead-free ceramic coating is provided. The method includes providing a lead-free ceramic composition with a crystalline phase of perovskite structure. The ceramic composition has a general formula of: (1-a)(K_{b}Na_{c}X_{d})(NbₑY_{f}Z_{g})O₃−aE, wherein X is one of an alkali metal, a transition metal and a post-transition metal; each of Y and Z is one of a transition metal and a metalloid; E is a metal oxide; 0≦a≦0.05; 0.4≦b≦0.6; 0.4≦c≦0.6; 0≦d≦0.2; 0.8≦e≦1; 0≦f≦0.2; 0≦g≦0.2; b+c+d=1; and e+f+g=1. The ceramic composition is heated to at least a partially molten state and the at least partially molten ceramic composition is deposited onto a substrate. The deposited ceramic composition is cooled and the deposited ceramic composition re-crystallizes on cooling to form the lead-free ceramic coating with a single crystalline phase of perovskite structure.

### FIELD OF THE INVENTION

The present invention relates to electronic ceramic materials and more particularly to a method of making a lead-free ceramic coating.

### BACKGROUND OF THE INVENTION

Thermal spray coatings are often used as wear, corrosion and oxidation resistant barriers in aggressive environments, resulting in increased durability as compared with uncoated components. Thermal spray is a continuous and directed coating deposition process in which coating materials are heated by electrical (plasma or arc) or chemical (combustion flame) means and sprayed onto substrates. The coating materials are usually fed in the form of powder, which is heated to a molten or semi-molten state and accelerated towards substrates in the form of micro-meter-size particles.

In recent years, attention has been paid to use of the thermal spray process for the deposition of electronic ceramic materials to produce electric devices such as capacitors and sensors. There have been some development efforts as reported for exploring thermal sprayed piezoelectric ceramic coatings, which are conventionally deposited by methods such as spin-coating, physical vapour deposition and screen printing. Compared to the other coating methods, such as solution coating and screen-printing of ceramic paste, the thermal spray process has advantages in high productivity, large thickness range, large area, less limited selection of substrates, which has potential values for realizing piezoelectric sensors and transducers for effective structure and condition monitoring.

Thermal spray deposition of lead zirconate titanate (PZT), a commercially dominant piezoelectric ceramic, has been investigated, but the coatings showed a large proportion of amorphous and non-perovskite secondary phases and no substantial piezoelectric response is obtained even after post-spray heat treatment. Moreover, the large amount of toxic lead in PZT limits the implementation in high temperature thermal spray due to the serious environment pollution and health hazard. For environmentally friendly lead-free piezoelectric ceramics, efforts have been made on thermal sprayed barium titanate (BaTiO₃) coatings. Although piezoelectricity has been observed in the coatings, the piezoelectric coefficient is very low (d₃₃<15 pC/N) due to the significant amount of amorphous and non-perovskite secondary phases existing in the coatings. In addition, the Curie temperature of BaTiO₃ is very low, just 120° C., above which the piezoelectric property will be completely lost. Hence the coatings are not useful for practical piezoelectric-related applications.

It is therefore desirable to provide a method of making a lead-free ceramic coating with good piezoelectric performance and that does not pose environmental and health problems.

### SUMMARY OF THE INVENTION

Accordingly, in a first aspect, the present invention provides a method of making a lead-free ceramic coating. The method includes providing a lead-free ceramic composition with a crystalline phase of perovskite structure. The ceramic composition has a general formula of: (1-a)(K_{b}Na_{c}X_{d})(NbₑY_{f}Z_{g})O₃−aE, wherein X is one of an alkali metal, a transition metal and a post-transition metal; each of Y and Z is one of a transition metal and a metalloid; E is a metal oxide; 0≦a≦0.05; 0.4≦b≦0.6; 0.4≦c≦0.6; 0≦d≦0.2; 0.8≦e≦1; 0≦f≦0.2; 0≦g≦0.2; b+c+d=1; and e+f+g=1. The ceramic composition is heated to at least a partially molten state and the at least partially molten ceramic composition is deposited onto a substrate. The deposited ceramic composition is cooled and the deposited ceramic composition re-crystallizes on cooling to form the lead-free ceramic coating with a single crystalline phase of perovskite structure.

Other aspects and advantages of the invention will become apparent from the following detailed description, taken in conjunction with the accompanying drawings, illustrating by way of example the principles of the invention.

### BRIEF DESCRIPTION OF THE DRAWINGS

Embodiments of the invention will now be described, by way of example only, with reference to the accompanying drawings, in which:

FIG. 1A is a schematic diagram showing a set-up for making a lead-free ceramic coating in accordance with one embodiment of the present invention;

FIG. 1B is an enlarged schematic view of portion A of FIG. 1A;

FIG. 2 is a schematic flow diagram illustrating a method of making a lead-free ceramic coating in accordance with one embodiment of the present invention;

FIG. 3A is an enlarged schematic partial cross-sectional view of an electronic device having a lead-free ceramic coating in accordance with one embodiment of the present invention;

FIG. 3B is an enlarged schematic partial cross-sectional view of an electronic device having a lead-free ceramic coating in accordance with another embodiment of the present invention;

FIG. 4 is a graph showing the particle size distribution of a 0.94(K_{0.5}Na_{0.5})NbO₃−0.06LiNbO₃ (“KNN-LN”) ceramic powder in accordance with one embodiment of the present invention;

FIG. 5A is a photo showing a lead-free KNN-LN ceramic coating deposited on an aluminium (Al) alloy substrate;

FIG. 5B is a photo showing a lead-free KNN-LN ceramic coating deposited on a steel substrate;

FIG. 5C is a photo showing a lead-free KNN-LN ceramic coating deposited on an alumina substrate with a palladium (Pd)/silver (Ag) (30/70) lower electrode;

FIG. 6 is a graph showing X-ray diffraction (XRD) patterns of the KNN-LN ceramic powder and lead-free KNN-LN ceramic coatings formed using a thermal spray apparatus at different power settings;

FIG. 7 is a graph showing XRD patterns of the lead-free KNN-LN ceramic coatings after heat treatment;

FIGS. 8A through 8C are scanning electron microscopy (SEM) images of surfaces of the lead-free KNN-LN ceramic coatings;

FIGS. 9A through 9C are SEM images of cross-sections of the lead-free KNN-LN ceramic coatings;

FIGS. 10A through 10C are SEM images of surfaces of the lead-free KNN-LN ceramic coatings after heat treatment;

FIGS. 11A through 11C are SEM images of cross-sections of the lead-free KNN-LN ceramic coatings after heat treatment;

FIG. 12 is a graph showing the dielectric properties of a lead-free KNN-LN ceramic coating after heat treatment;

FIG. 13 is a three-dimensional graph showing vibrational data of the lead-free KNN-LN ceramic coating after heat treatment;

FIG. 14 is a graph showing the particle size distribution of a (K_{0.44}Na_{0.52}Li_{0.04})(Nb_{0.84}Ta_{0.10}Sb_{0.06})O₃ (“KNN-LiTaSb”) ceramic powder in accordance with another embodiment of the present invention;

FIG. 15A is a photo showing a lead-free KNN-LiTaSb ceramic coating deposited on an aluminium (Al) alloy substrate;

FIG. 15B is a photo showing a lead-free KNN-LiTaSb ceramic coating deposited on a steel substrate;

FIG. 15C is a photo showing a lead-free KNN-LiTaSb ceramic coating deposited on an alumina substrate with a palladium (Pd)/silver (Ag) (30/70) lower electrode;

FIG. 16 is a graph showing XRD patterns of the KNN-LiTaSb ceramic powder, a lead-free KNN-LiTaSb ceramic coating and the lead-free KNN-LiTaSb ceramic coating after heat treatment;

FIGS. 17A and 17B are SEM images of surfaces of the lead-free KNN-LiTaSb ceramic coating and the lead-free KNN-LiTaSb ceramic coating after heat treatment;

FIGS. 18A and 18B are SEM images of cross-sections of the lead-free KNN-LiTaSb ceramic coating and the lead-free KNN-LiTaSb ceramic coating after heat treatment;

FIG. 19 is a graph showing the dielectric properties of the lead-free KNN-LiTaSb ceramic coating after heat treatment; and

FIG. 20 is a graph showing vibrational data of the lead-free KNN-LiTaSb ceramic coating after heat treatment.

### DETAILED DESCRIPTION OF EXEMPLARY EMBODIMENTS

The detailed description set forth below in connection with the appended drawings is intended as a description of presently preferred embodiments of the invention, and is not intended to represent the only forms in which the present invention may be practiced. It is to be understood that the same or equivalent functions may be accomplished by different embodiments that are intended to be encompassed within the scope of the invention.

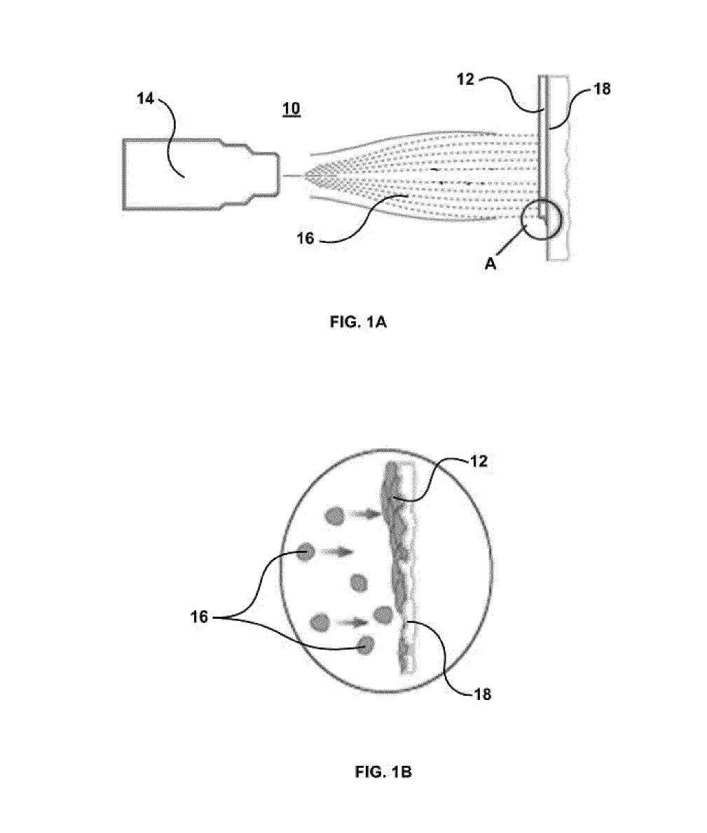

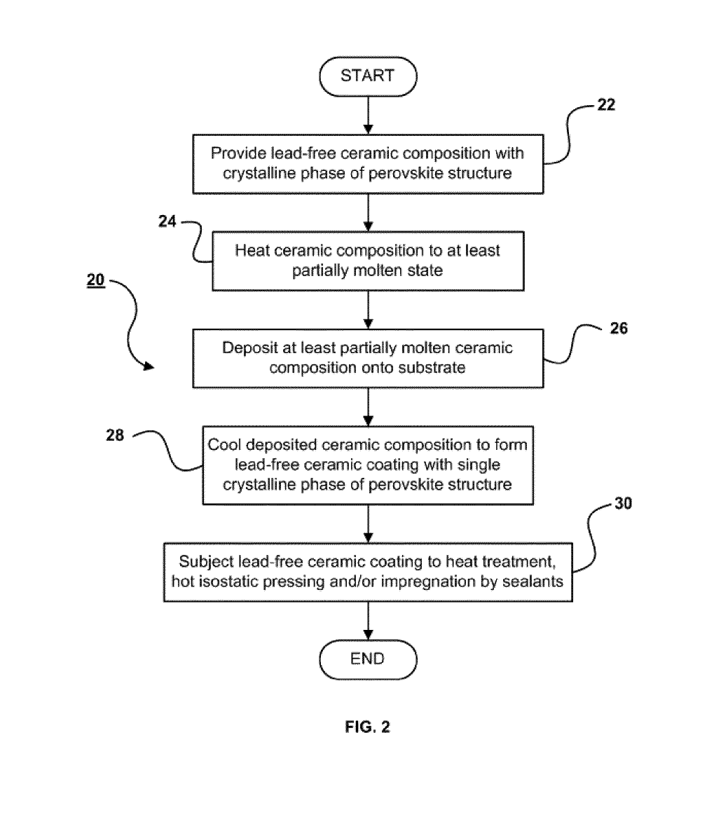

Referring now to FIG. 1 A, a set-up 10 for making a lead-free ceramic coating 12 is shown. In the present embodiment, the set-up 10 includes a thermal spray apparatus 14 that is arranged to deposit a lead-free ceramic composition 16 in a molten or semi-molten state onto a surface 18 to form the lead-free ceramic coating 12.

The lead-free ceramic coating 12 has a substantially single crystalline phase of perovskite structure. This may be determined by X-ray diffraction (XRD). The X-ray diffraction (XRD) peaks of the perovskite structure may be indexed in terms of potassium niobate (KNbO₃) Joint Committee on Powder Diffraction Standards (JCPDS) No. 32-0822 and JCPDS No. 71-0945, respectively as a reference.

In one embodiment, the lead-free ceramic coating 12 has a general formula of:

(K_{b}Na_{c}X_{d})(NbₑY_{f}Z_{g})O₃−aE (1-a)

where: X is one of an alkali metal, a transition metal and a post-transition metal; each of Y and Z is one of a transition metal and a metalloid; E is a metal oxide; 0≦a≦0.05; 0.4≦b≦0.6; 0.4≦c≦0.6; 0≦d≦0.2; 0.8≦e≦1; 0≦f≦0.2; 0≦g≦0.2; b+c+d=1; and e+f+g=1. In one embodiment, X may be one of lithium (Li), bismuth (Bi) and iron (Fe). In the same or a different embodiment, each of Y and Z may be one of tantalum (Ta), antimony (Sb), titanium (Ti) and vanadium (V) and/or E may be one of CuO, ZnO and BaTiO₃. In one embodiment, the lead-free ceramic coating 12 may be one of:

(K_{0.47}Na_{0.47}Li_{0.06})NbO₃,

(K_{0.44}Na_{0.52}Li_{0.04})(Nb_{0.84}Ta_{0.10}Sb_{0.06})O₃; and

(K_{0.4644}Na_{0.5156}Bi_{0.002})(Nb_{0.912}Sb_{0.048}Zr_{0.04})O₃.

The lead-free ceramic coating 12 may have a porosity of less than about 20%. In one embodiment, the lead-free ceramic coating 12 may have a porosity of less than about 10%. The lead-free ceramic coating 12 may have an effective piezoelectric coefficient (d₃₃) of greater than about 85 picometer per volt (pm/V).

Various types of thermal spray apparatus may be employed. The thermal spray apparatus 14 may be a plasma spray apparatus such as, for example, an Air Plasma Spray (APS), a Vacuum Plasma Spray (VPS) or an Induction Plasma Spray with a supersonic nozzle (IPSS), or a High Velocity Oxy-Fuel (HVOF) Spray.

The surface 18 may be that of a conductive substrate, a non-conductive substrate or a conductive layer formed on a non-conductive substrate. The conductive layer may function as a lower electrode. The conductive substrate may be a metal such as, for example, aluminium alloy or steel. The non-conductive substrate may be a ceramic material such as, for example, alumina or zirconia. The conductive layer may be a metal such as, for example, platinum or an alloy of palladium/silver (e.g., Pd/Ag 30/70) or a conductive oxide such as, for example, LaNiO₃, La_{0.5}Sr_{0.5}CoO₃ or La_{0.7}Sr_{0.3}MnO₃. The conductive layer may be deposited by screen-printing, sputtering or thermal spraying to a thickness of between about 1 micron (μm) and about 10 μm.

To improve surface conditions for deposition of the lead-free ceramic composition 16, the surface 18 may be sand-blasted with, for example, 20 to 80 mesh alumina powder (that is, alumina powder having a particle diameter of between about 177 μm and about 841 μm) and then cleaned with a solvent that does not leave a residue, such as, for example, acetone, to give a suitable substrate surface for subsequent thermal spray.

Referring now to FIG. 2, a method 20 of making a lead-free ceramic coating 12 using the set-up 10 of FIG. 1A will now be described. The method 20 begins at step 22 by providing a lead-free ceramic composition 16 with a crystalline phase of perovskite structure, that is, the perovskite phase is substantially the only crystalline phase. This may be determined by X-ray diffraction (XRD). The lead-free ceramic composition 16 may be a potassium sodium niobate (KNN) based lead-free oxide composition with a single phase of perovskite structure. In one embodiment, the ceramic composition 16 may have a general formula of:

(K_{b}Na_{c}X_{d})(NbₑY_{f}Z_{g})O₃−aE (1-a)

where: X is one of an alkali metal, a transition metal and a post-transition metal such as, for example, lithium (Li), bismuth (Bi) or iron (Fe); each of Y and Z is one of a transition metal and a metalloid such as, for example, tantalum (Ta), antimony (Sb), titanium (Ti) or vanadium (V); E is a metal oxide such as, for example, CuO, ZnO or BaTiO₃; 0≦a≦0.05; 0.4≦b≦0.6; 0.4≦c≦0.6; 0≦d≦0.2; 0.8≦e≦1; 0≦f≦0.2; 0≦g≦0.2; b+c+d=1; and e+f+g=1.

To compensate for loss of alkali ion composition during processing due to volatility, the ceramic composition 16 includes an excess of between about 1 and about 20 mol % of alkali metal ions over a desired stoichiometry. An excess 1 to 20 mol % of alkali ions may be added in the lead-free ceramic composition 16 over the targeted stoichiometry.

The lead-free ceramic composition 16 with perovskite crystalline phase may be prepared from a solid-state reaction or a wet chemical process using a precursor solution. In one embodiment, the ceramic composition 16 may be prepared from a mixture of one or more metal oxides and one or more metal carbonates selected from a group consisting of K₂CO₃, Na₂CO₃, Nb₂O₅, Li₂CO₃, Ta₂O₅, Sb₂O₅, Bi₂O₃ and ZrO₂. The mixture of the one or more metal oxides and the one or more metal carbonates may be calcined at a temperature of between about 750 degrees Celsius (° C.) and about 950° C. for a period of between about 1 hour and 6 hours, preferably at a temperature of about 850° C. for a period of about 5 hours, to form the ceramic composition 16.

In the present embodiment, the ceramic composition 16 is in powder form with a particle size of between about 0.5 microns (μm) and about 100 μm. In one embodiment, the ceramic composition 16 may have a particle size of between about 5 μm and about 80 μm. The powder particles may be of a substantially single phase of perovskite structure and of any suitable shape, typically spherical or irregular in certain instances.

At step 24, the ceramic composition 16 is heated to at least a partially molten state. This may be by heating the ceramic composition 16 to a temperature of around or above a melting point of the ceramic composition 16.

In the present embodiment, the lead-free ceramic coating 12 is produced via a thermal spray technique. In this embodiment, the ceramic composition 16 may be supplied or fed at a rate of between about 10 grams per minute (g/min) and about 30 g/min into the thermal spray apparatus 14. In one embodiment, the ceramic composition 16 may be fed at a rate of between about 15 g/min and about 25 g/min into the thermal spray apparatus 14. The ceramic composition 16 that is transferred to the thermal spray apparatus 14 is injected into the high temperature flame of the spray torch where the ceramic composition 16 is heated to a molten or a semi-molten state. In one embodiment, the thermal spray apparatus 14 may be set to a plasma power of between about 17 kilowatt (kW) to about 28 kW, more preferably, a plasma power of between about 17 kW and about 25 kW.

The at least partially molten ceramic composition 16 is deposited at step 26 onto a substrate. As part of the thermal spray process, the ceramic composition 16 that is heated to the molten or semi-molten state exits the thermal spray apparatus 14 in a stream of molten or semi-molten particles as a spray plume directed towards the prepared surface 18. The substrate may be one of a conductive substrate, a non-conductive substrate and a conductive layer formed on a non-conductive substrate. The substrate may be at room temperature during thermal spraying process. The at least partially molten ceramic composition 16 may be deposited at a distance D of between about 50 millimetres (mm) and about 150 mm from a nozzle of the thermal spray apparatus 14. In one embodiment, the thermal spray apparatus 14 may be positioned a distance D of between about 75 mm and about 120 mm from the prepared surface 18. During the deposition process, the thermal spray apparatus 14 may be moved in a plane parallel to the prepared surface 18 to ensure even distribution of the ceramic composition 16.

With reference to FIG. 1B, the ceramic composition 16 that exits the thermal spray apparatus 14 is accelerated towards the prepared surface 18 where the ceramic composition 16 is deposited, coating the prepared surface 18. The deposited ceramic composition 16 is cooled at step 28 and re-crystallizes on cooling to form the lead-free ceramic coating 12. In the present embodiment, the droplets of the ceramic composition 16 spread upon impact and solidify rapidly. The perovskite structure of the thermal sprayed coating is formed simultaneously with the coating formation during the thermal spray process of the molten or semi-molten ceramic powder with a prior formed perovskite structure. The deposited coatings are built up by successive deposition of the droplets until the desired thickness is reached. As will be apparent to those of ordinary skill in the art, the thickness of the lead-free ceramic coating 12 is a function of coating time and other spray parameters. The lead-free ceramic coating 12 may be formed to a thickness of between about 1 μm and about 500 μm. In one embodiment, the lead-free ceramic coating 12 is formed to a thickness of between about 50 μm and about 200 μm.

The as-sprayed coatings have a highly crystallized perovskite phase, and if poled, give a piezoelectric response. Achieving optimal coating quality via thermal spraying is dependent on key parameters such as starting powder, plasma power, feeding rate and torch-substrate distance. In addition, other process parameters or conditions may also be adjusted to achieve the optimal coating quality. In the present embodiment, the as-sprayed coatings are crystallized into a single phase of crystalline perovskite structure with low porosity (typically a porosity of less than about 20%, preferably below about 10%) by controlling the spray parameters.

Post-spray treatments may be applied to the lead-free ceramic coating 12. In the present embodiment, the lead-free ceramic coating 12 is subjected at step 30 to one or more of a heat treatment process, hot isostatic pressing and impregnation by sealants. Advantageously, the heat treatment process reduces the quenching-induced amorphous phase and thus improves the crystallinity of the lead-free ceramic coating 12. Further advantageously, the heat treatment process also significantly enhances the piezoelectric response of the lead-free ceramic coating 12. The heat treatment process may involve firing the lead-free ceramic coating 12 and may be performed at a temperature of between about 800° C. and about 1,500° C. depending on the composition of the lead-free ceramic composition 16. In one embodiment, the heat treatment process may be performed at a temperature of between about 1,000° C. and about 1,200° C. The heat treatment process may include application of a radiation based heating technique where thermal energy may be controlled to be concentrated on the lead-free ceramic coating 12 to minimize the thermal impact on the substrate. The radiation based heat treatment process may include one or more radiation based heating techniques such as laser glazing and laser spike annealing. In the same or a different embodiment, other post-spray treatments such as hot isostatic pressing and impregnation by sealants may be applied on the lead-free ceramic coating 12 to reduce porosity. After the optional post-spray treatments, the lead-free ceramic coating 12 may become denser with further improved crystallinity and piezoelectric performance properties, providing greater value for applications in piezoelectric sensors and transducers.

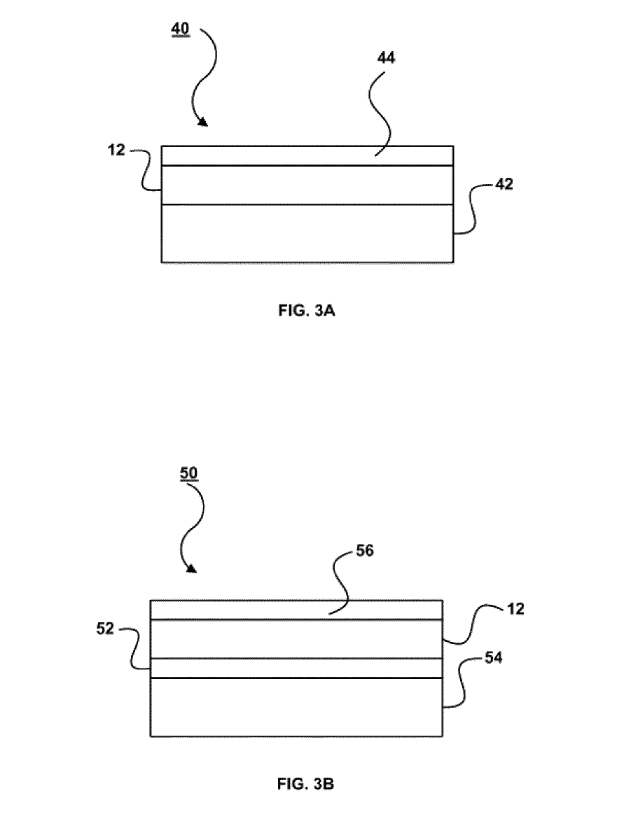

Referring now to FIG. 3A, an enlarged schematic partial cross-sectional view of an electronic device 40 having a lead-free ceramic coating 12 formed in accordance with the method 20 described above is shown. In this embodiment, the lead-free ceramic coating 12 is formed on a conductive substrate 42 and a conductive layer 44 is coated on the lead-free ceramic coating 12 as an upper electrode.

Referring now to FIG. 3B, an enlarged schematic partial cross-sectional view of another electronic device 50 having a lead-free ceramic coating 12 formed in accordance with the method 20 described above is shown. The present embodiment differs from the previous embodiment in that the lead-free ceramic coating 12 is formed on a first conductive layer 52 formed on a non-conductive substrate 54 and a second conductive layer 56 is formed on the lead-free ceramic coating 12 as an upper electrode.

In both embodiments, the conductive layers 44 and 56 may be formed of a metal such as, for example, silver and may be deposited by methods such as, for example, screen-printing, sputtering or thermal spraying. The conductive layers 44 and 56 may be formed to a thickness of between about 1 micron (μm) and about 10 μm.

An electrical or electromechanical device having a coating of lead-free ceramic coating 12 formed according to the method 20 described above may be used in many applications such as, for example, capacitors, piezoelectric sensors, actuators, acoustic and energy harvesting transducers.

### EXAMPLE 1

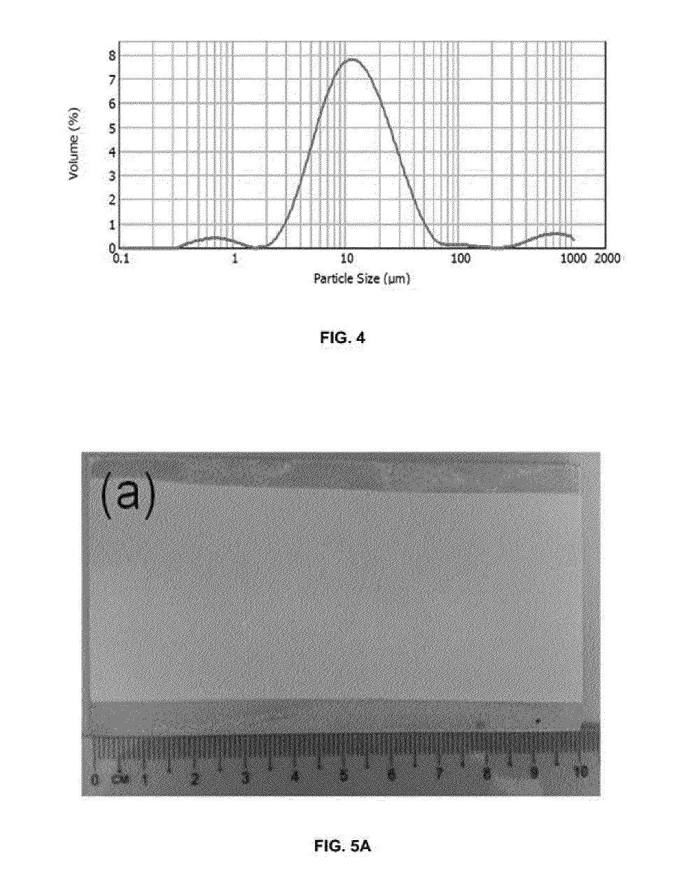

K₂CO₃, Na₂CO₃, Nb₂O₅ and Li₂CO₃ powders were used as starting materials to produce a lead-free oxide ceramic with a composition of 0.94(K_{0.5}Na_{0.5})NbO₃−0.06LiNbO₃ (“KNN-LN”). The respective starting materials were weighed according to the targeted chemical stoichiometry. To compensate for loss of K and Na during subsequent high temperature processing, an excess of 10 mol % of K and Na was introduced. As the carbonate powders are moisture sensitive, the carbonate powders were first dried before use to avoid compositional errors. The weighed materials were wet-mixed for 24 hours in a ball mill by the use of ethanol and a ZrO₂ ball. The slurry was then dried and crushed before it was calcined at 850° C. for 5 hours in an alumina crucible. The calcined ceramic powder was crushed by mortar and pestle and then classified by sieving to achieve the desired distribution of particle size. Referring now to FIG. 4, a graph of the particle size distribution of the KNN-LN ceramic powder is shown. As can be seen from FIG. 4, the volume median diameter D (0.5), which is the diameter where 50% of the distribution is above and 50% is below, of the ceramic particle is 12.5 μm.

The KNN-LN ceramic powder was coated on different types of substrates including alumina, aluminium alloy and steel. Before coating, the alumina substrates were cleaned by ethanol and coated with screen-printed Pd/Ag (30/70) as a lower electrode. Deposition of the lower electrode may not be required for conductive substrates such as aluminium alloy and steel. Instead, sand blasting by alumina particles was performed to roughen the substrate surface in order to have better adhesion with the coatings.

The KNN-LN ceramic powder was sprayed onto the substrates using a Sulzer Metco atmospheric plasma spraying (APS) system at ambient pressure. The powder was fed into a plasma torch where an inert gas like argon (Ar) was used as the plasma gas. The energy of the plasma was enhanced by the addition of bimolecular gases (H₂, N₂) which were added as secondary gases. The powder particles were heated to a molten or a semi-molten state and accelerated to the substrate by the plasma flame. The flame was directed normal to the surface of the substrates. The substrates were held at a certain distance away from the plasma torch. The preferred parameters are shown in Table 1 below.

TABLE 1

| Parameter | Preferred Range |
|---|---|
| Particle size of the ceramic powder | 0.5-100 μm, preferably 5-80 μm |
| Power of the plasma | 17-28 kW, preferably 17-25 kW |
| Torch-substrate distance | 50-150 mm, preferably 75-120 mm |
| Feeding rate | 10-30 g/min, preferably 15-25 g/min |

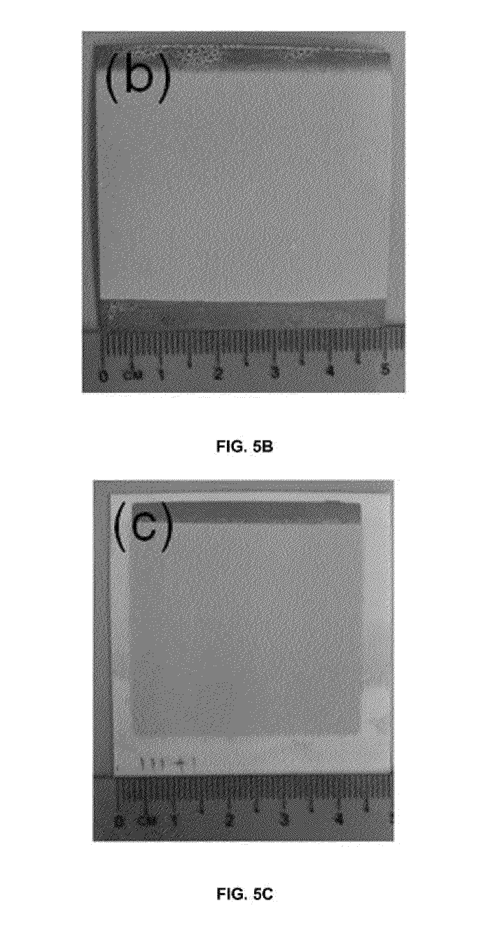

The powder exhibited good wetting in the formation of the coatings and the coatings showed good integrity and adhesion on the substrates. Referring now to FIGS. 5A through 5C, photographic images of the thermal sprayed KNN-LN ceramic coatings on different substrates are shown. More particularly, FIG. 5A is a photo showing the KNN-LN ceramic coating deposited on an aluminium (Al) alloy substrate, FIG. 5B is a photo showing the KNN-LN ceramic coating deposited on a steel substrate, and FIG. 5C is a photo showing the KNN-LN ceramic coating deposited on an alumina substrate with a palladium (Pd)/silver (Ag) (30/70) lower electrode.

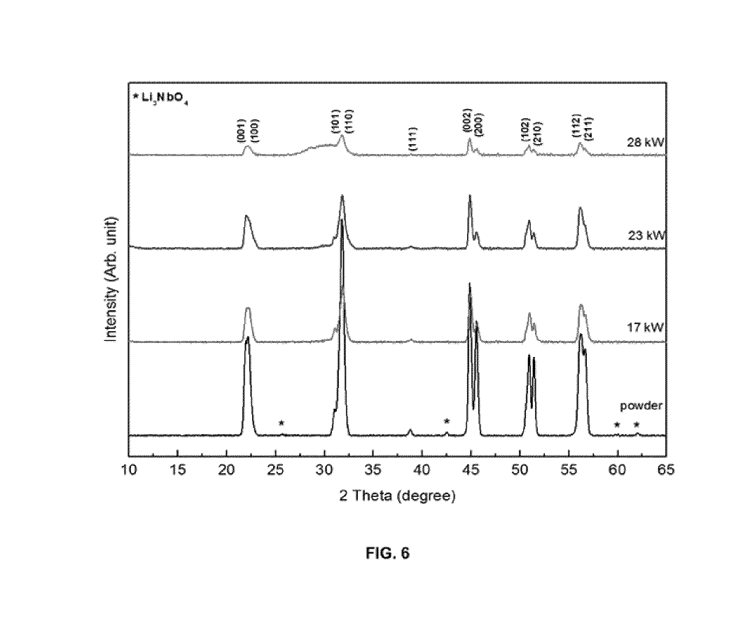

Referring now to FIG. 6, the crystal structure of the KNN-LN powder and coatings was analysed by XRD and FIG. 6 is a graph showing X-ray diffraction (XRD) patterns of the KNN-LN ceramic powder and lead-free KNN-LN ceramic coatings formed using a thermal spray apparatus at different power settings. As can be seen from FIG. 6, the KNN-LN powder possesses perovskite crystal structure with very minor Li₃NbO₄ secondary phase, while the KNN-LN ceramic coatings have a single crystalline phase of perovskite structure. The crystal structure comparison between the KNN-LN ceramic powder and the KNN-LN ceramic coatings indicates that the thermal energy during the thermal spray process results in the desired conversion of the secondary phase to perovskite structure during the melt-recrystallization process of the powder.

The KNN-LN ceramic coatings sprayed at low power (that is, 17 kW and 23 kW) exhibited sharp XRD peaks without apparently detectable amorphous humps, indicating the high crystallinity of the coating. This is distinct from the structure of other perovskite oxide ceramics coated by thermal spray as reported in literature. The observed single phase of perovskite structure and high crystallinity of the sprayed KNN-LN ceramic coatings may be mainly attributed to the high mobility of the alkali ions. Compared to the ions of other perovskite oxide ceramic material in literature such as lead, barium and strontium, the sodium, potassium and lithium ions in this case have higher mobility and thus the crystallization rate of the KNN-LN based ceramic may be higher. As a result, when the molten or semi-molten particles impact on the substrate surface and solidify, higher crystallinity is obtained.

On the other hand, considerable amorphous phase was found in the coating sprayed at very high power (that is, 28 kW) as evidenced by the substantially lower diffraction peaks and the diffuse peak in the range of 25 to 33°.

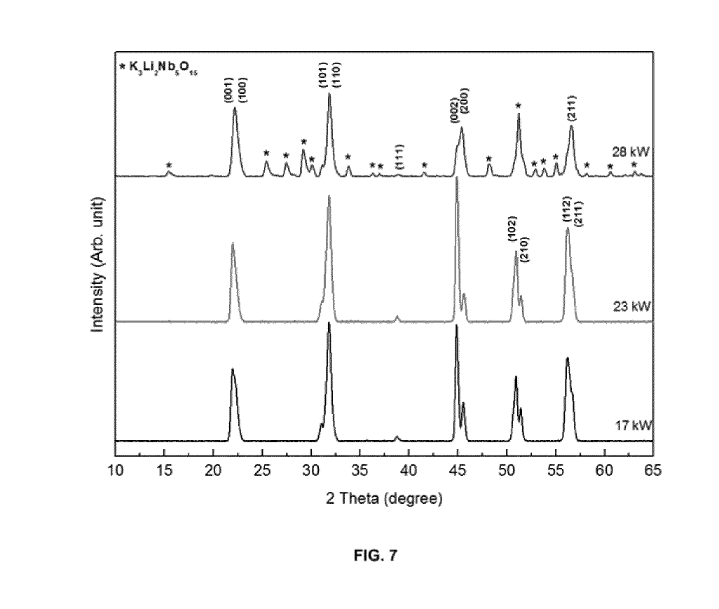

Referring now to FIG. 7, some of the coatings underwent a post-spray heat treatment at 1,050° C. and FIG. 7 is a graph showing XRD patterns of the KNN-LN ceramic coatings after heat treatment. The KNN-LN ceramic coatings that were sprayed at low power showed a single phase of perovskite structure with diffraction peaks stronger than those of the as-sprayed ones, indicating a further increase of crystallinity by the heat treatment. In contrast, the coating sprayed at 28 kW showed mixed crystalline phases of perovskite structure and K₃Li₂Nb₅O₁₅. The observed secondary phase of the coating after heat treatment suggests that significant thermal decomposition of the KNN-LN powder occurs when sprayed at high power. Thermal decomposition of the powder is related to the loss of Na and K during the spraying process, which increases with increasing plasma power. As a result, the stoichiometry of the coating sprayed at high power is significantly different from that of the powder. During the heat treatment, the materials with the changed stoichiometry crystallize to a structure different from the desired perovskite phase.

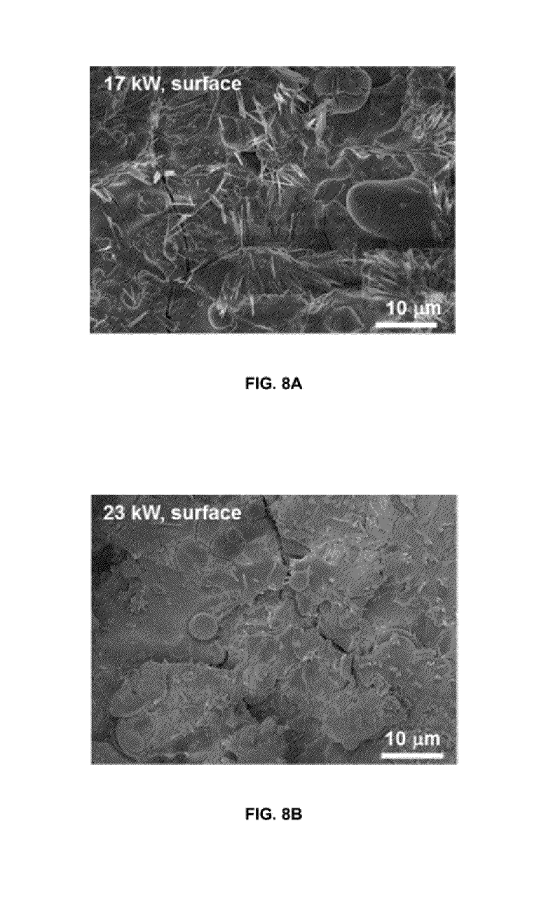

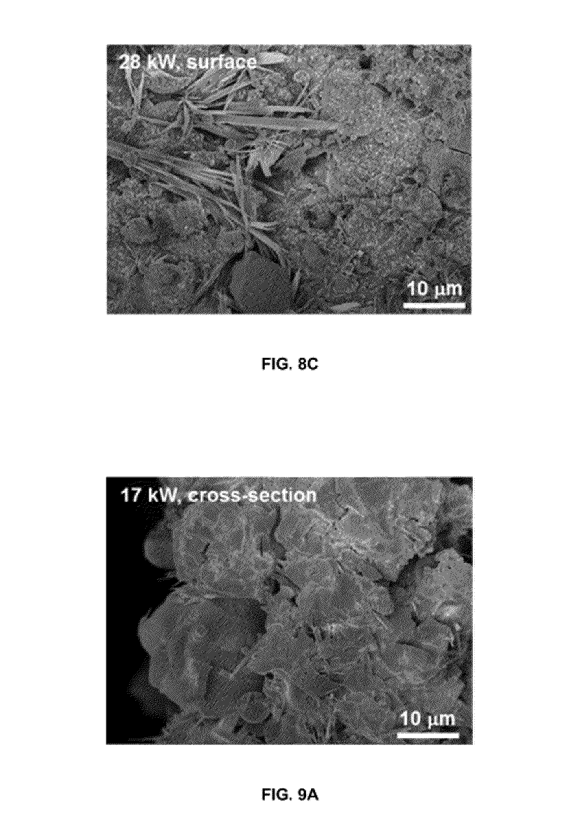

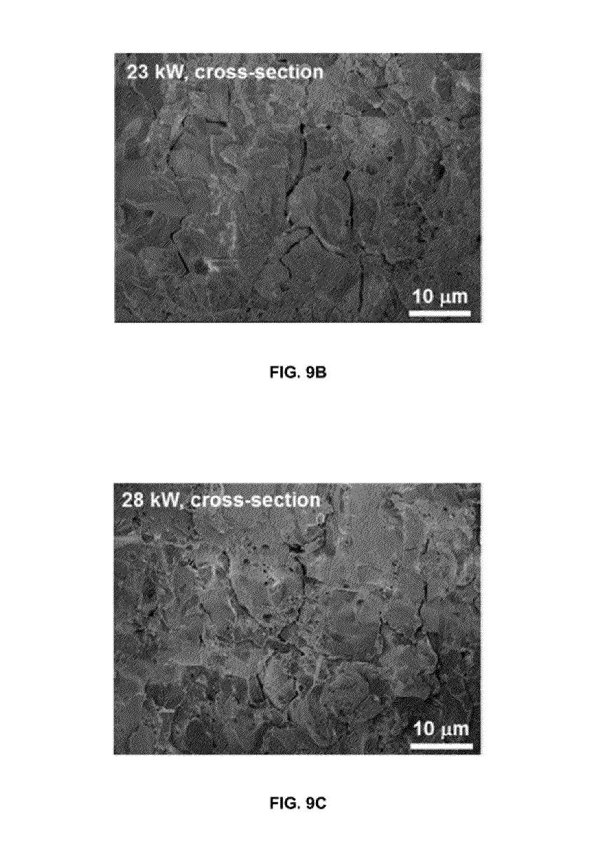

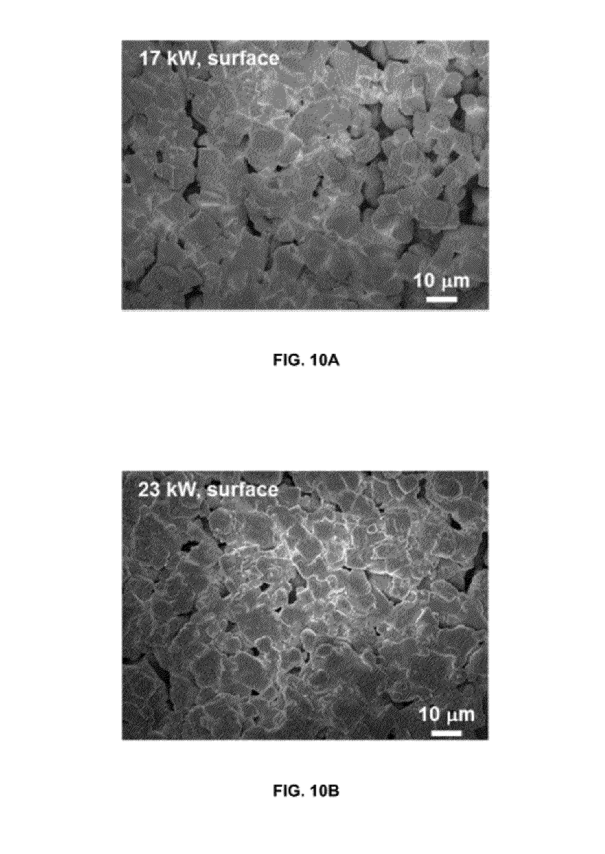

Referring now to FIGS. 8A through 8C and FIGS. 9A through 9C, the surface and cross-sectional morphology of the as-sprayed KNN-LN coatings under scanning electron microscopy (SEM) inspection is shown. More particularly, FIGS. 8A through 8C are SEM images of surfaces of the KNN-LN ceramic coatings and FIGS. 9A through 9C are SEM images of cross-sections of the KNN-LN ceramic coatings. As can be seen from FIGS. 8A through 8C and FIGS. 9A through 9C, all the coatings sprayed at different powers show a relatively dense surface. The surface of the coatings shows typical signs of a liquid phase, suggesting the occurrence of a melt-recrystallization process during the formation of the coatings. In addition, large numbers of needle-shaped crystals can be seen on the coating surface of the coating produced under a high power deposition condition, which may be a secondary phase resulting from crystallization of the materials with the changed stoichiometry.

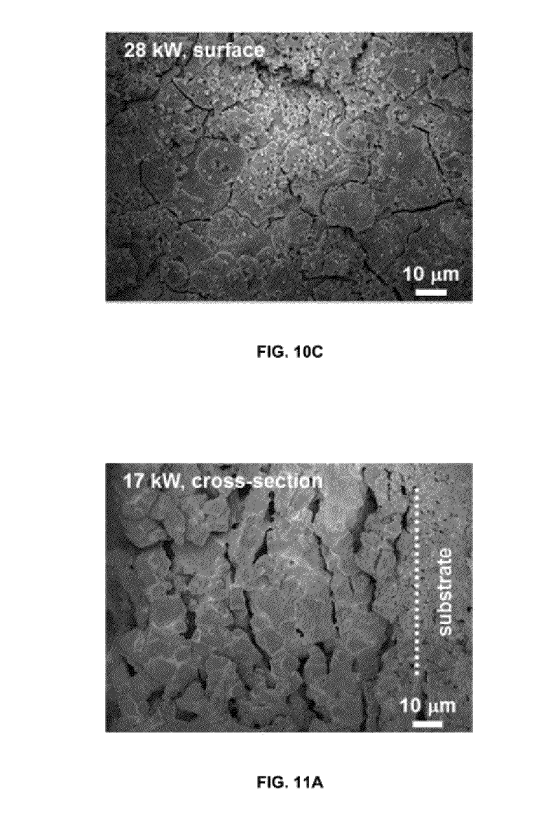

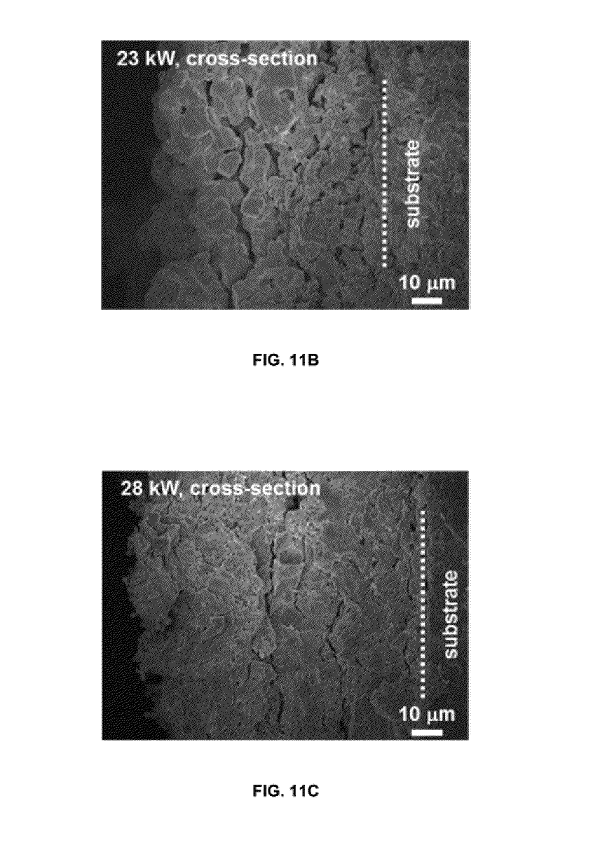

Referring now to FIGS. 10A through 10C and FIGS. 11A through 11C, SEM images of the surfaces and the cross-sections of the KNN-LN ceramic coatings after heat treatment are shown. As can be seen from FIGS. 10A through 10C and FIGS. 11A through 11C, a significant change of morphology was found after the heat treatment at 1,050° C. The coatings sprayed at low power (that is, 17 kW and 23 kW) demonstrated cubic-shaped grains with an average size of around 10 μm, which are similar to those typically observed in KNN based bulk ceramics. This indicates the significantly increased crystallinity as a result of the heat treatment, which is consistent with the XRD results. In contrast, no cubic shaped grains were found on the coating sprayed at high power (that is, 28 kW), suggesting the limited crystallinity of KNN based perovskite structure in the coating. This is consistent with the observed secondary phase and lower peaks in the XRD results of this coating.

For electrical characterization, patterns of silver (Ag) were deposited on the coatings as the upper electrode. The as-sprayed coatings showed high leakage current, while the coatings after heat treatment showed significantly reduced leakage current.

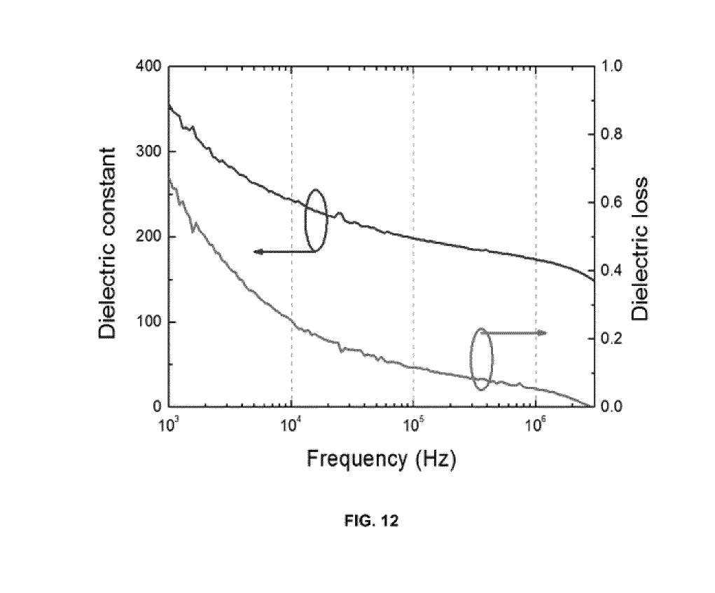

Referring now to FIG. 12, a graph of the dielectric response of the KNN-LN coating sprayed at 17 kW after heat treatment is shown. At a frequency of 10 kiloHertz (kHz), the dielectric constant and loss are 244 and 0.24, respectively. The dielectric constant of the coating is similar to that of the KNN-LN bulk ceramic, but the dielectric loss is higher, mainly due to the higher porosity compared to bulk ceramic.

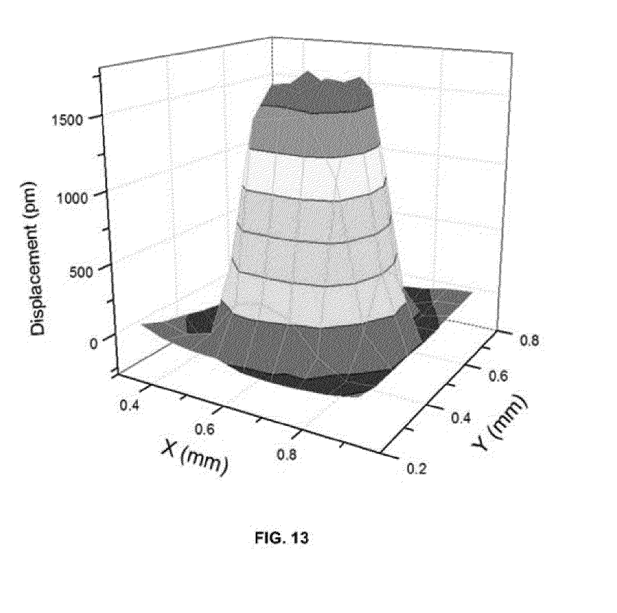

To characterize the piezoelectric property, the coatings were poled at 40 kilovolt per centimetre (kV/cm) for 30 minutes (min) at 120° C. in silicone oil and were tested by a laser scanning vibrometer (LSV). The as-sprayed coatings showed a relatively weak piezoelectric response, with an effective piezoelectric coefficient (d₃₃) of approximately 5 picometer per volt (pm/V) measured under the constraint of the substrate. The coatings after heat treatment demonstrated a strong piezoelectric response. Referring now to FIG. 13, a three-dimensional graph of the instantaneous vibration data when the displacement magnitude of the heat-treated KNN-LN coating sprayed at 17 kW reaches the maximum in the electric sine wave driving is shown. The central protruding area is the electrically excited area under the upper electrode, whereas the flat surrounding area is the KNN-LN coating without the upper electrode cover. During testing, a unipolar alternating current (ac) signal of 20 volt (V) amplitude at 1 kiloHertz (kHz) was applied to the sample. The effective piezoelectric coefficient d₃₃ value of the KNN-LN coating is 85 pm/V under the substrate clamping. The actual piezoelectric coefficient d₃₃ without substrate clamping may be significantly higher, well above 120 pm/V. The measured piezoelectric properties of the thermal sprayed coatings are comparable to those of bulk ceramic and the disclosed method may be employed in piezoelectric applications.

### EXAMPLE 2

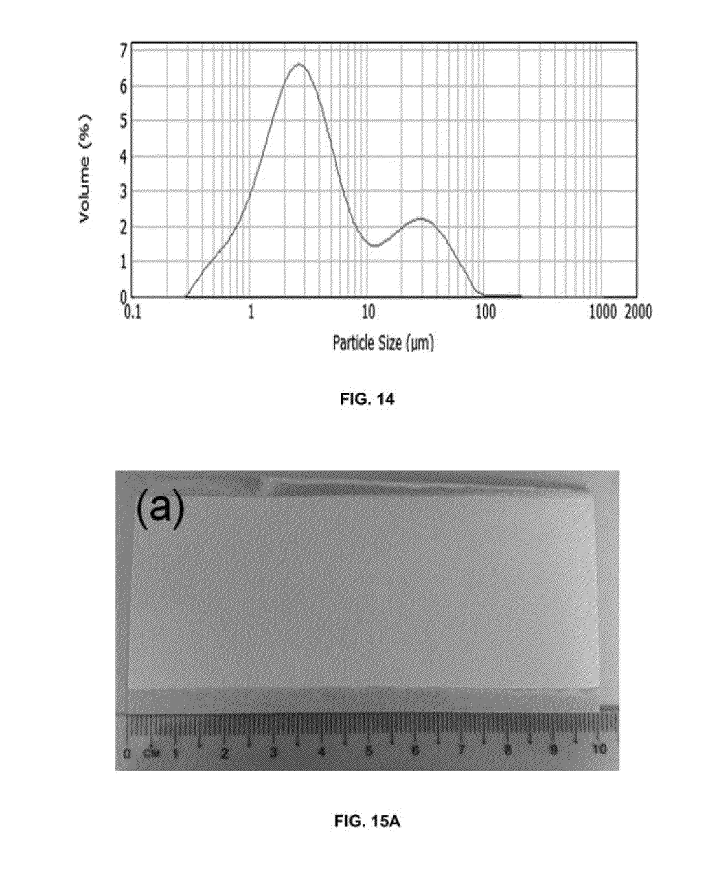

Powders of K₂CO₃, Na₂CO₃, Nb₂O₅, Li₂CO₃, Ta₂O₅ and Sb₂O₅ were used as starting materials. The amount of the respective powders were stoichiometrically weighed to achieve a targeted composition of (K_{0.44}Na_{0.52}Li_{0.04}(Nb_{0.84}Ta_{0.10}Sb_{0.06})O₃ (“KNN-LiTaSb”). To compensate for loss of K and Na during subsequent high temperature processing, an excess of 10 mol % K and Na was introduced. As the carbonate powders are moisture sensitive, the carbonate powders were first dried before use to avoid compositional errors. The weighed materials were wet-mixed for 24 hours in a ball mill by the use of ethanol and a ZrO₂ ball. The slurry was then dried and crushed before it was calcined at 850° C. for 5 hours in an alumina crucible. The calcined ceramic powder was crushed by mortar and pestle and then classified by sieving to achieve the desired distribution of particle size. Referring now to FIG. 14, a graph of the particle size distribution of the KNN-LiTaSb ceramic powder is shown.

The KNN-LiTaSb ceramic powder was sprayed onto the substrates using a Sulzer Metco plasma spray system using the parameters listed in Table 2 below.

TABLE 2

| Parameter | Preferred Range |
|---|---|
| Particle size of the ceramic powder | 0.5-100 μm, preferably 5-80 μm |
| Power of the plasma | 17-28 kW, preferably 17-25 kW |
| Torch-substrate distance | 50-150 mm, preferably 75-120 mm |
| Feeding rate | 10-30 g/min, preferably 15-25 g/min |

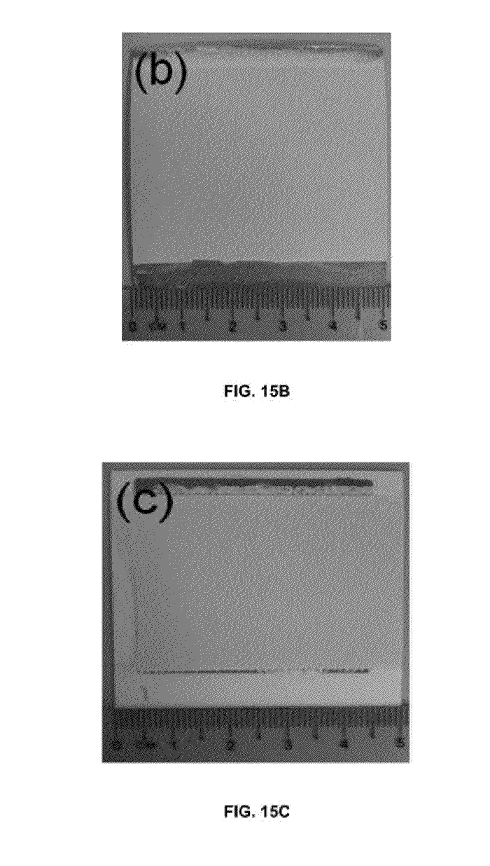

Referring now to FIGS. 15A through 15C, photographic images of the thermal sprayed KNN-LiTaSb ceramic coatings on different substrates are shown. More particularly, FIG. 15A is a photo showing the KNN-LiTaSb ceramic coating deposited on an aluminium (Al) alloy substrate, FIG. 15B is a photo showing the KNN-LiTaSb ceramic coating deposited on a steel substrate, and FIG. 15C is a photo showing the KNN-LiTaSb ceramic coating deposited on an alumina substrate with a palladium (Pd)/silver (Ag) (30/70) lower electrode;

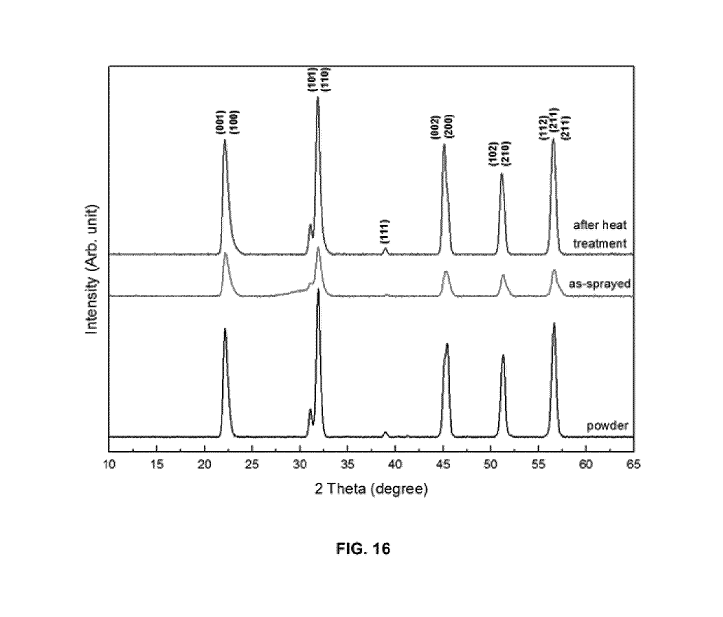

Referring now to FIG. 16, the KNN-LiTaSb powder and coatings were examined by X-ray diffraction and the results are shown in FIG. 16. As can be seen from FIG. 16, the KNN-LiTaSb powder and coatings all possess a single crystalline phase of perovskite structure. As can be seen also from FIG. 16, the heat treatment at 1,050° C. significantly enhanced the crystallinity of the KNN-LiTaSb coatings.

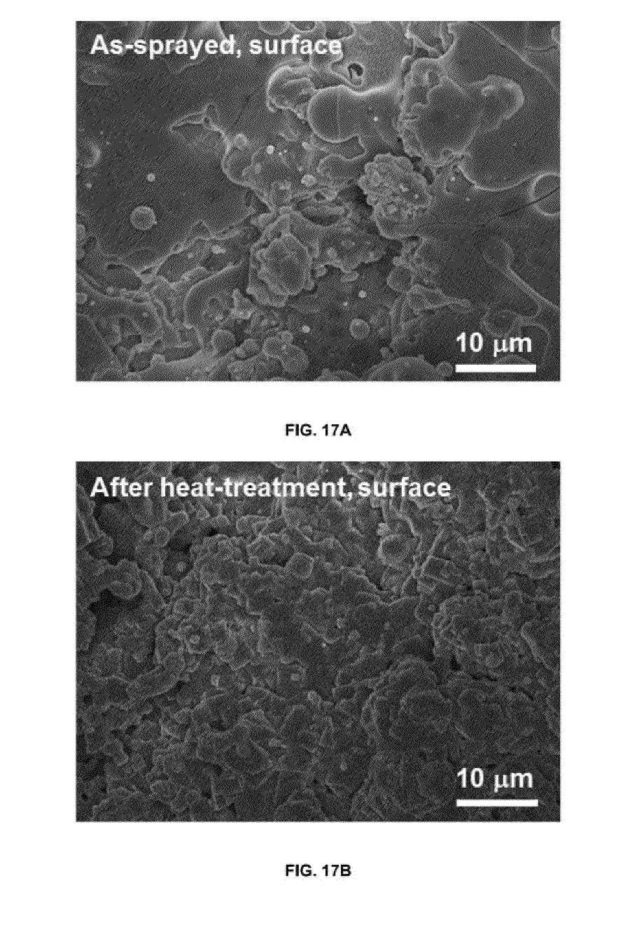

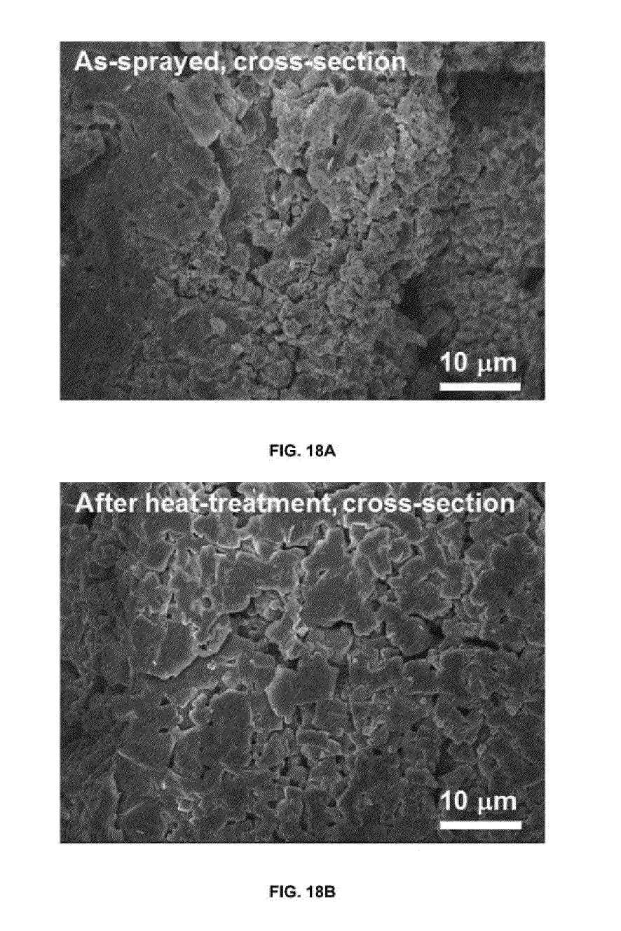

Referring now to FIGS. 17A and 17B and FIGS. 18A and 18B, surface and cross-sectional morphology of the heat-treated KNN-LiTaSb coatings under scanning electron microscopy (SEM) inspection is shown. More particularly, FIGS. 17A and 17B are SEM images of surfaces of the as-sprayed lead-free KNN-LiTaSb ceramic coating and the heat-treated lead-free KNN-LiTaSb ceramic coating and FIGS. 18A and 18B are SEM images of cross-sections of the as-sprayed lead-free KNN-LiTaSb ceramic coating and the heat-treated lead-free KNN-LiTaSb ceramic coating. The surface of the as-sprayed KNN-LiTaSb coatings shows typical signs of a liquid phase, while the KNN-LiTaSb coating after heat treatment shows cubic shaped grains. The cross-sectional SEM inspection shows low porosity for both the as-sprayed and heat-treated KNN-LiTaSb coatings.

For electrical characterization, patterns of silver (Ag) were deposited on the coatings as the upper electrode. The as-sprayed coatings showed high leakage current, while the coatings after heat treatment showed significantly reduced leakage current.

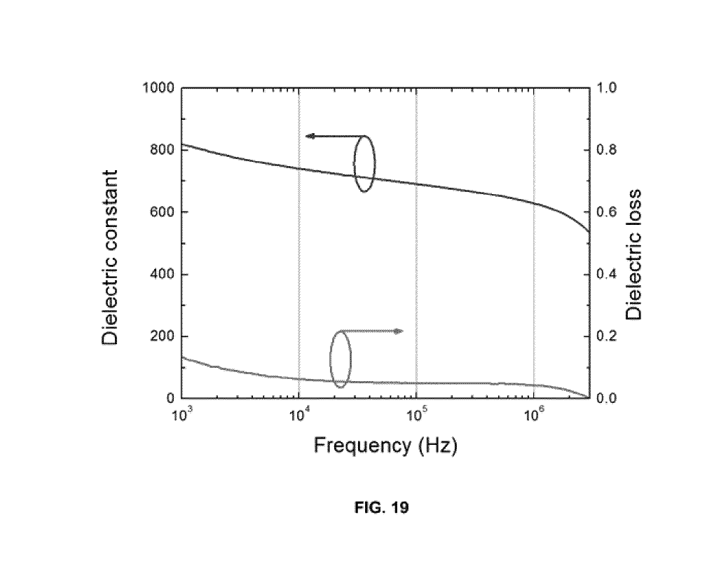

Referring now to FIG. 19, a graph of the dielectric response of the KNN-LiTaSb coating after heat treatment is shown. At a frequency of 10 kHz, the dielectric constant and loss are 736 and 0.06, respectively.

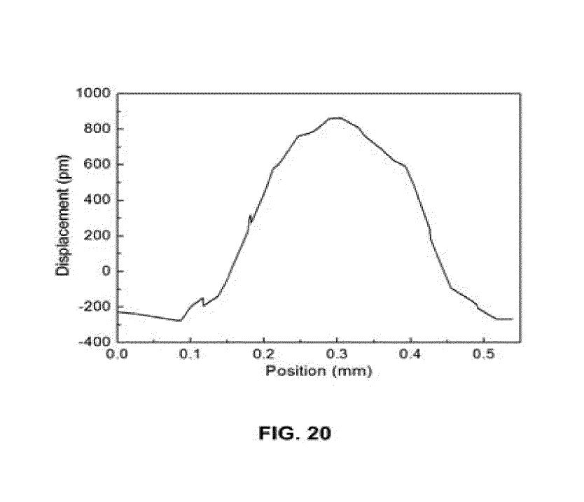

Referring now to FIG. 20, a graph of the vibrational data of the lead-free KNN-LiTaSb ceramic coating after heat treatment is shown. The vibrational data were obtained by a laser scanning vibrometer when the displacement magnitude of the coating reaches the maximum in the electric sine wave driving. The central protruding area is the electrically excited area under the upper electrode, whereas the flat surrounding area is the coating without the upper electrode cover. During the testing, a unipolar alternating current (ac) signal of 10 V amplitude at 1 kHz was applied to the coating. The effective piezoelectric constant d₃₃ under substrate clamping is 112 pm/V for the KNN-LiTaSb coating after heat treatment.

### EXAMPLE 3

Powders of K₂CO₃, Na₂CO₃, Bi₂O₃, Nb₂O₅, Sb₂O₅, ZrO₂ were used as starting materials. The amount of the respective materials were stoichiometrically weighed for a targeted ceramic composition of (K_{0.4644}Na_{0.5156}Bi_{0.02})(Nb_{0.912}Sb_{0.048}Zr_{0.04})O₃ (KNB-NSZ). To compensate for loss of K and Na during subsequent high temperature processing, an excess of 10 mol % K and Na was introduced during weighing. As the carbonate powders are moisture sensitive, the carbonate powders were first dried before use to avoid compositional errors. The weighed materials were wet-mixed for 24 hours in a ball mill by the use of ethanol and ZrO₂ ball. The slurry was then dried and crushed before it was calcined at 850° C. for 5 hours in an alumina crucible.

The calcined KNB-NSZ ceramic powder was crushed by mortar and pestle and then classified by sieving to achieve a desired distribution of particle size. The KNB-NSZ ceramic powder was then sprayed onto the substrates using a Sulzer Metco plasma spray system with the preferred parameters listed in Table 3 below.

TABLE 3

| Parameter | Preferred Range |
|---|---|
| Particle size of the ceramic powder | 0.5-100 μm, preferably 5-80 μm |
| Power of the plasma | 17-28 kW, preferably 17-25 kW |
| Torch-substrate distance | 50-150 mm, preferably 75-120 mm |
| Feeding rate | 10-30 g/min, preferably 15-25 g/min |

While specific compositions and parameters were detailed in the above examples, it will be apparent to those of ordinary skill in the art that modifications and changes may be made therein without departing from the scope of the present invention.

As is evident from the foregoing discussion, the present invention provides a method of making a lead-free ceramic coating. Being free of lead, the ceramic coating of the present invention is environmentally friendly and does not pose a health risk. Further advantageously, the lead-free ceramic coating of the present invention in both as-sprayed and heat-treated forms exhibit a single phase of perovskite structure and low porosity. In terms of piezoelectric capabilities, the heat-treated lead-free ceramic coating of the present invention is able to achieve a superior piezoelectric performance with an effective piezoelectric coefficient d₃₃ of greater than about 85 pm/V, which is comparable to that of its bulk ceramic counterpart. The method of the present invention provides a high throughput, scalable method of forming lead-free piezoelectric oxide ceramic coatings on various types of substrates including those with non-flat surfaces or complex geometries. Advantageously, the method of the present invention can be used to generate thick coatings more effectively over a large area at high deposition rate. Another advantage of the method of the present invention is that it can be performed with equipment that is readily available in the manufacturing industry.

The present invention is suitable for application in piezoelectric and acoustic sensors, actuators, and transducers for condition and structural health monitoring in transportation, aerospace, marine offshore, machine intelligence, and civil engineering applications.

While preferred embodiments of the invention has been illustrated and described, it will be clear that the invention is not limited to the described embodiments only. Numerous modifications, changes, variations, substitutions and equivalents will be apparent to those skilled in the art without departing from the scope of the invention as described in the claims.

Further, unless the context clearly requires otherwise, throughout the description and the claims, the words “comprise”, “comprising” and the like are to be construed in an inclusive as opposed to an exclusive or exhaustive sense; that is to say, in the sense of “including, but not limited to”.

1. A method of making a lead-free ceramic coating, comprising:
providing a lead-free ceramic composition with a crystalline phase of perovskite structure, wherein the ceramic composition has a general formula of:
(K_{b}Na_{c}X_{d})(NbₑY_{f}Z_{g})O₃−aE (1-a)
wherein
X is one of an alkali metal, a transition metal and a post-transition metal;
each of Y and Z is one of a transition metal and a metalloid;
E is a metal oxide;
0≦a≦0.05;
0.4≦b≦0.6;
0.4≦c≦0.6;
0≦d≦0.2;
0.8≦e≦1;
0≦f≦0.2;
0≦g≦0.2;
b+c+d=1; and
e+f+g=1;
heating the ceramic composition to at least a partially molten state;
depositing the at least partially molten ceramic composition onto a substrate; and
cooling the deposited ceramic composition, wherein the deposited ceramic composition re-crystallizes on cooling to form the lead-free ceramic coating with a single crystalline phase of perovskite structure.

2. The method of claim 1, wherein the ceramic composition comprises an excess of between about 1 and about 20 mol % of alkali metal ions over a desired stoichiometry.

3. The method of claim 1, wherein the ceramic composition is prepared from a mixture of one or more metal oxides and one or more metal carbonates selected from a group consisting of K₂CO₃, Na₂CO₃, Nb₂O₅, Li₂CO₃, Ta₂O₅, Sb₂O₅, Bi₂O₃ and ZrO₂.

4. The method of claim 3, wherein the mixture of the one or more metal oxides and the one or more metal carbonates is calcined at a temperature of between about 750 degrees Celsius (° C.) and about 950° C. for a period of between about 1 hour and 6 hours.

5. The method of claim 1, wherein X is one of lithium (Li), bismuth (Bi) and iron (Fe).

6. The method of claim 1, wherein each of Y and Z is one of tantalum (Ta), antimony (Sb), titanium (Ti) and vanadium (V).

7. The method of claim 1, wherein E is one of CuO, ZnO and BaTiO₃.

8. The method of claim 1, wherein the lead-free ceramic coating is one of:
(K_{0.47}Na_{0.47}Li_{0.06})NbO₃;
(K_{0.44}Na_{0.52}Li_{0.04})(Nb_{0.84}Ta_{0.10}Sb_{0.06})O₃; and
(K_{0.4644}Na_{0.5156}Bi_{0.002})(Nb_{0.912}Sb_{0.048}Zr_{0.04})O₃.

9. The method of claim 1, wherein the lead-free ceramic coating has a porosity of less than about 20%.

10. The method of claim 1, wherein the lead-free ceramic coating has an effective piezoelectric coefficient (d₃₃) of greater than about 85 picometer per volt (pm/V).

11. The method of claim 1, wherein the ceramic composition is in powder form with a particle size of between about 0.5 microns (μm) and about 100 μm.

12. The method of claim 1, further comprising feeding the ceramic composition at a rate of between about 10 grams per minute (g/min) and about 30 g/min into a thermal spray apparatus.

13. The method of claim 12, wherein the at least partially molten ceramic composition is deposited at a distance of between about 50 millimetres (mm) and about 150 mm from a nozzle of the thermal spray apparatus.

14. The method of claim 1, wherein the substrate is one of a conductive substrate, a non-conductive substrate and a first conductive layer formed on a non-conductive substrate.

15. The method of claim 14, further comprising forming a second conductive layer on the lead-free ceramic coating.

16. The method of claim 1, wherein the lead-free ceramic coating is formed to a thickness of between about 10 μm and about 500 μm.

17. The method of claim 1, further comprising subjecting the lead-free ceramic coating to one or more of a heat treatment process, hot isostatic pressing and impregnation by sealants.

18. The method of claim 17, wherein the heat treatment process is performed at a temperature of between about 800° C. and about 1,500° C.

19. The method of claim 17, wherein the heat treatment process comprises application of a radiation based heating technique.

20. The method of claim 19, wherein the radiation based heating technique is one of laser glazing and laser spike annealing.
